(19) United States
(12) Patent Application Publication
(10) Pub. No.: US 2025/0285876 A1
(43) Pub. Date: Sep. 11, 2025

(54) PROCESS FOR FABRICATING AN ELECTRONIC DEVICE

(71) Applicant: STMicroelectronics International N.V., Geneva (CH)

(72) Inventor: Franck JULIEN, La Penne sur Huveaune (FR)

(73) Assignee: STMicroelectronics International N.V., Geneva (CH)

(21) Appl. No.: 19/069,708

(22) Filed: Mar. 4, 2025

(30) Foreign Application Priority Data
Mar. 5, 2024 (FR) FR2402184

(51) Int. Cl. H01L 21/3115; H01L 21/311

(52) U.S. Cl. CPC H01L 21/31155; H01L 21/31111

(57) ABSTRACT

A method of manufacturing an electronic device includes the doping by ion implantation of a first portion of the silicon nitride layer overlying a dielectric layer, where a second portion of the silicon nitride layer is protected from the ion implantation. A partial etching of the silicon nitride layer is then performed to etch the first portion down to a first depth smaller than or equal to a thickness of the silicon nitride layer and etch the second portion down to a second depth smaller than the first depth. The partial etching forms an etched silicon nitride layer having a cavity in all or part of the first portion. The cavity is filled with a polysilicon material to for a transistor gate.

### PRIORITY CLAIM

This application claims the priority benefit of French Application for Patent No. 2402184, filed on Mar. 5, 2024, the content of which is hereby incorporated by reference in its entirety to the maximum extent allowable by law.

### TECHNICAL FIELD

The present disclosure generally concerns electronic devices, and in particular the manufacturing of electronic devices.

The present disclosure concerns, in particular, the manufacturing of an electronic device comprising an electronic component in a trench in a semiconductor substrate and another electronic component on the same semiconductor substrate.

### BACKGROUND

During the manufacturing of an electronic device comprising different electronic components inside and on top of a same semiconductor substrate, a manufacturer may seek to use a same manufacturing method for all or part of the electronic components, in particular for reasons of manufacturing cost. For example, the electronic components of the electronic device may be manufactured on a same production line. However, if the manufacturing method is entirely implemented on the entire semiconductor substrate, without any separate treatment such as the fact of providing protections, such as masks, any implemented treatment applies to all electronic components. Now, a treatment used to form an electronic component may be unsuitable for another electronic component, and it is generally necessary to provide protections, such as masks, so that certain treatments do not apply to all electronic components.

According to the electronic device to be manufactured, and in particular to the different electronic components to be formed inside and on top of the same semiconductor substrate, it may be complicated, or even impossible, to manufacture the different electronic components on the same production line. For example, it may be necessary to implement specific technological steps to form an electronic component in a trench, or vertical electronic component, in the semiconductor substrate and other specific technological steps to form another electronic component on the semiconductor substrate (so-called “planar” electronic component) which may be difficult to reconcile with the specific technological steps for forming the trench electronic component.

It should be specified that, when it is indicated that the electronic component is “on the semiconductor substrate”, this does not necessarily mean that all the elements of this electronic component are on the semiconductor substrate, and other elements may be formed in the semiconductor substrate but not in a trench formed in the semiconductor substrate.

The electronic component in a trench may be, for example, a capacitor, a selection transistor, a vertical transistor or a transistor in a trench. The electronic component on the semiconductor substrate may be, for example, a MOS transistor or a gate.

Further, it is generally desired to use a number of protection masks which is the lowest possible.

There exists a need for a manufacturing method enabling to manufacture an electronic device comprising different electronic components inside and on top of a same semiconductor substrate, in particular an electronic component in a trench in the semiconductor substrate and another electronic component on the semiconductor substrate, and which does not require using specific technological steps to form all or part of the electronic components. It would be advantageous for this manufacturing method to use a decreased number of manufacturing steps, for example as many common manufacturing steps as possible, and/or as few protection masks as possible.

There is a need in the art to overcome all or part of the disadvantages of known electronic device manufacturing methods.

### SUMMARY

An embodiment provides a method of manufacturing an electronic device comprising: providing a semiconductor substrate covered with a dielectric layer; forming a silicon nitride layer of a first thickness on the dielectric layer; doping by ion implantation of a first portion of the silicon nitride layer located above a first semiconductor region of the semiconductor substrate, a second portion of said silicon nitride layer located above a second semiconductor region of the semiconductor substrate being protected from said ion implantation; and partially etching the silicon nitride layer, wherein the rate of etching of the first portion is greater than the rate of etching of the second portion so that the first portion is etched down to a first depth smaller than or equal to the first thickness and the second portion is etched down to a second depth smaller than the first depth, said partial etching forming an etched silicon nitride layer comprising a cavity in all or part of the first portion.

According to an embodiment, the rate of etching of the first portion is greater than four times the rate of etching of the second portion, for example greater than or equal to five times, or even ten times, the rate of etching of the second portion.

According to an embodiment, the etching of the first portion stops before, or at, the dielectric layer, the dielectric layer forming, for example, an etch stop layer for the silicon nitride, the dielectric layer being, for example, made of silicon oxide.

According to an embodiment, the method comprises forming an insulating trench in the semiconductor substrate between the first semiconductor region and the second semiconductor region, wherein forming said insulating trench is performed prior to forming the silicon nitride layer.

According to an embodiment, the method comprises forming a trench in the second semiconductor region through the silicon nitride layer and the dielectric layer, preferably prior to the partial etching of the silicon nitride layer, wherein forming said trench comprises, for example, a dry etching.

According to an embodiment, the method comprises forming a polysilicon filling layer so as to at least fill the cavity and the trench, and forming a first polysilicon region in said cavity and a second polysilicon region in said trench.

According to an embodiment, the method comprises forming a first layer of oxide, for example of silicon oxide, on the sides and the bottoms of the cavity and of the trench, prior to forming the filling layer.

According to an embodiment, the method comprises removing the etched silicon nitride layer, after forming the filling layer, said removing, for example, comprising a wet etching with a solution comprising phosphoric acid.

According to an embodiment, the method comprises forming a second oxide layer on the first and second polysilicon regions, and for example also on portions of the semiconductor substrate from which the dielectric layer has been removed, wherein forming the second oxide layer is carried out after removing the etched silicon nitride layer.

According to an embodiment, the method comprises removing a second thickness of polysilicon in the second polysilicon region from a first surface of the etched silicon nitride layer, the first polysilicon region being protected by a mask during this removal.

According to an embodiment, the first polysilicon region forms all or part of a first gate region of a first electronic component, said first gate region being on the first semiconductor region, and the second polysilicon region forms all or part of a second gate region of a second electronic component, said second gate region being in a trench in the second semiconductor region.

According to an embodiment, the first component is a MOS transistor, the method comprising: forming a doped well in the first semiconductor region, prior to forming the silicon nitride layer; forming insulating spacers on the sides of the first gate region; and forming drain and source regions in the first semiconductor region.

According to an embodiment, the second component is a transistor in a trench, for example a selection transistor in a trench.

According to an embodiment, the partial etching of the silicon nitride layer is a wet etching, for example with a solution comprising phosphoric acid or a solution based on hydrofluoric acid.

According to an embodiment: the first depth is greater than or equal to 80% of the first thickness, for example substantially equal to the first thickness; and/or the second depth is smaller than or equal to 50% of the first thickness, for example smaller than or equal to 20% of the first thickness, or even smaller than or equal to 10% of the first thickness.

According to an embodiment, the doping of the first portion of the silicon nitride layer is configured to less heavily dope a first sublayer in contact with the dielectric layer than a second sublayer above the first sublayer, so that, during the partial etching of the silicon nitride layer, the cavity formed in the silicon nitride layer comprises a first portion corresponding to the less heavily doped first sublayer and a second portion corresponding to the more heavily doped second sublayer, the second portion being wider than the first portion, for example the second portion having a domed shape wider than the first portion having a cylindrical shape.

Another embodiment provides an electronic device comprising: a first electronic component comprising a first gate region on a first semiconductor region of a semiconductor substrate; and a second electronic component comprising a second gate region in a trench in a second semiconductor region of the semiconductor substrate, the first gate region having a thickness greater than 50 nm, for example greater than or equal to 100 nm.

According to an embodiment, the first gate region comprises a first portion on the semiconductor substrate and a second portion on the first portion, the second portion being wider than the first portion, for example the first portion having a cylindrical shape and the second portion having a domed shape wider than the first portion.

An embodiment provides an electronic device likely to be obtained during one of the manufacturing methods described hereabove.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1A to 1Q are cross-section views showing steps of a method of manufacturing an electronic device;

FIG. 2 is a cross-section view showing an electronic device; and

FIGS. 3A and 3B are cross-section views showing a variant of the manufacturing method of FIGS. 1A to 1Q.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, not all the steps of the method of manufacturing the electronic components have been described, as they can be carried out with usual processes of microelectronics. Similarly, not all the details of the electronic components have been described. Further, not all the applications that the described electronic devices may have been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

When reference is made to a trench running through the semiconductor substrate, this does not mean that the trench necessarily extends across the entire thickness of the semiconductor substrate. The trench may be formed from an upper surface of the semiconductor substrate, which is the surface covered by the dielectric layer and the silicon nitride layer described later on.

When reference is made to an electronic component in a trench, reference is made to an electronic component mainly positioned in a trench running through the semiconductor substrate, for example comprising a gate which is included in the trench. When reference is made to a planar electronic component, or to an electronic component on the semiconductor substrate, reference is made to an electronic component which is not positioned in a trench running through the semiconductor substrate, and which comprises an element, for example a gate, positioned on the semiconductor substrate.

In the following description, the qualifiers “insulating” and “conductive” respectively signify, unless otherwise specified, electrically insulating and electrically conductive.

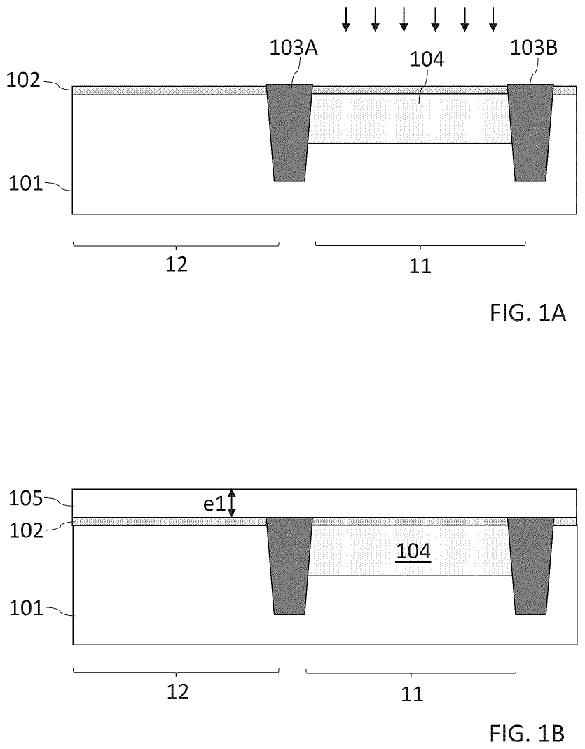

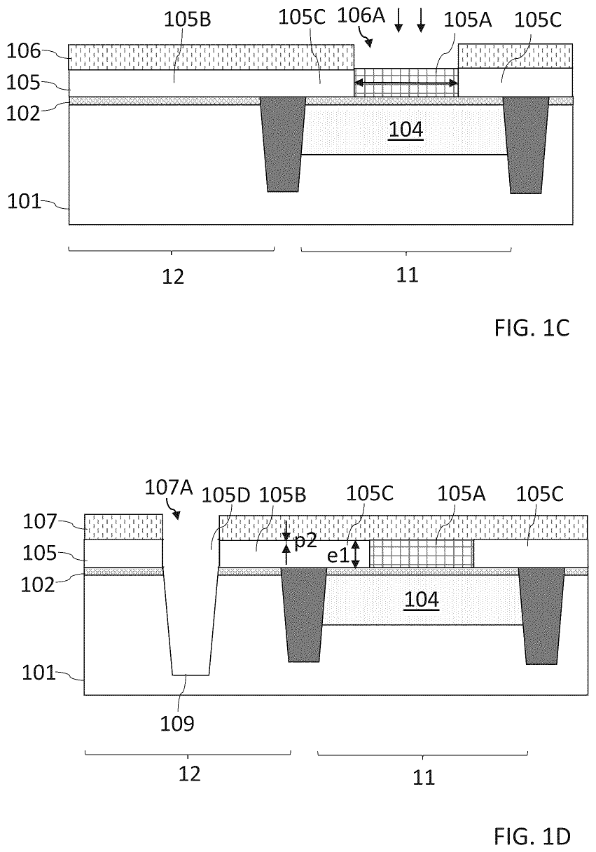

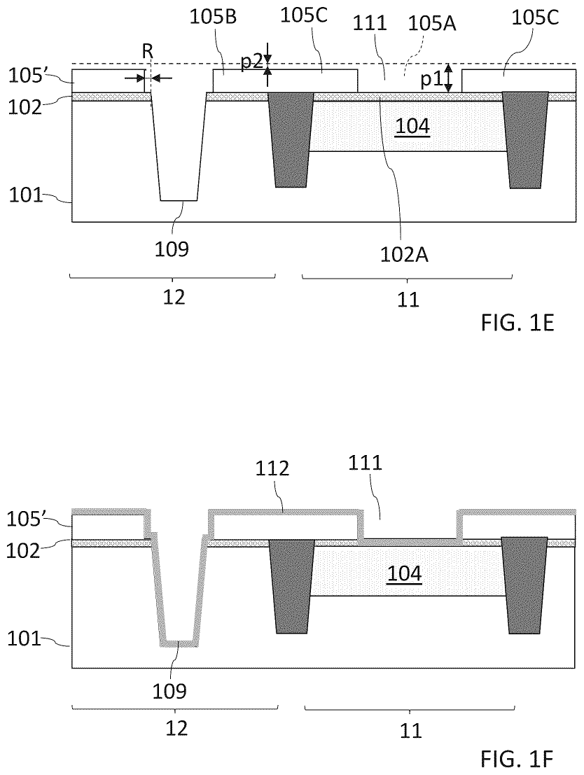

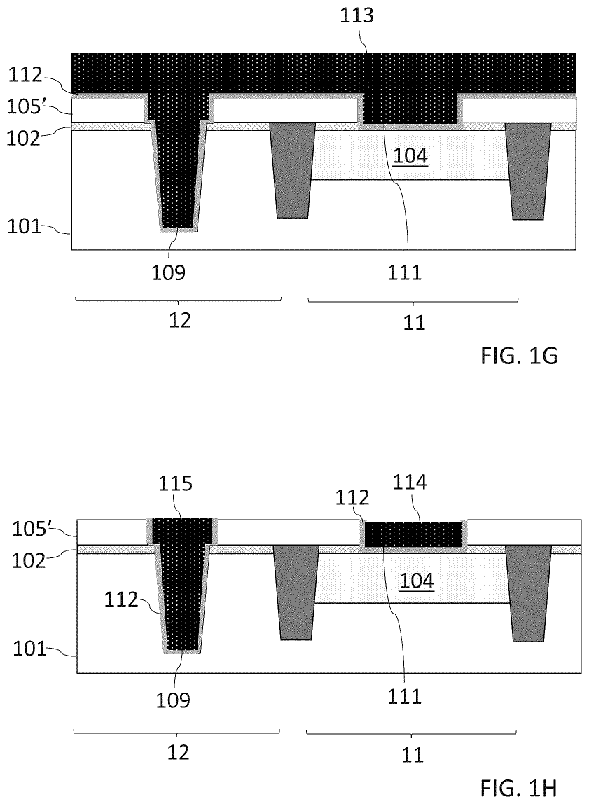

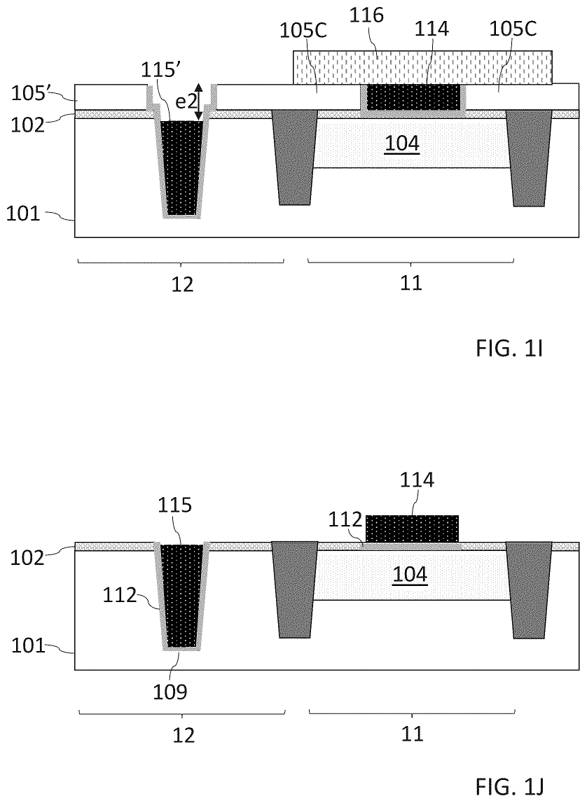

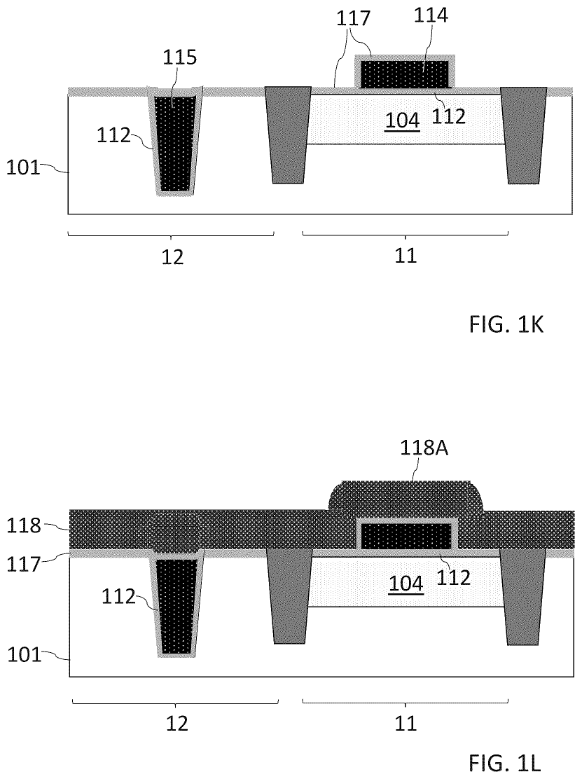

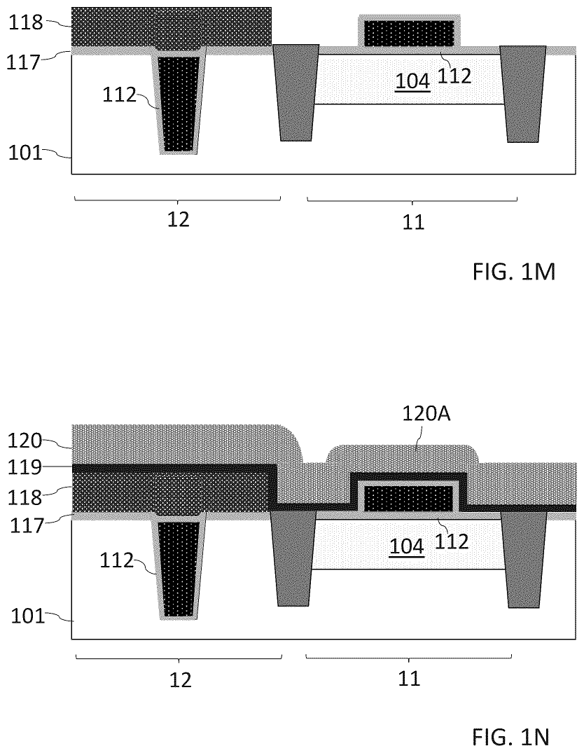

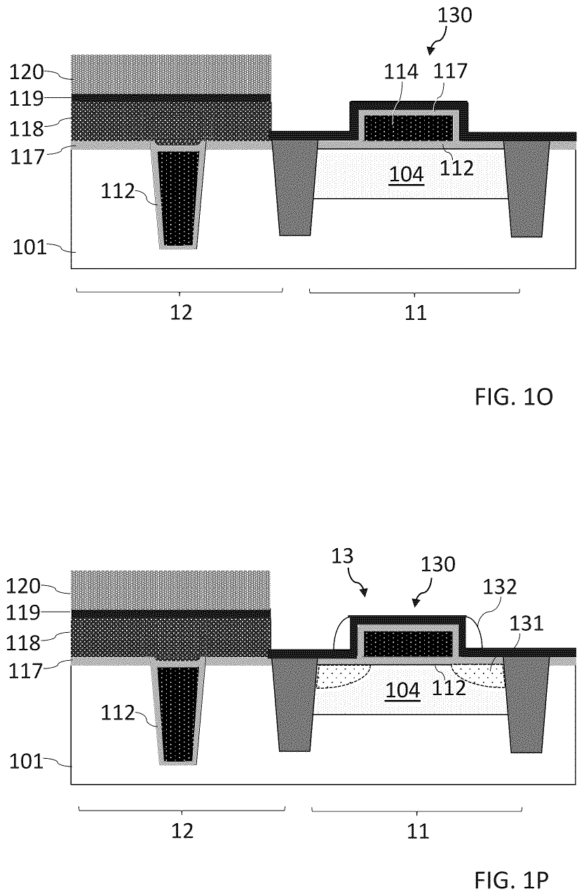

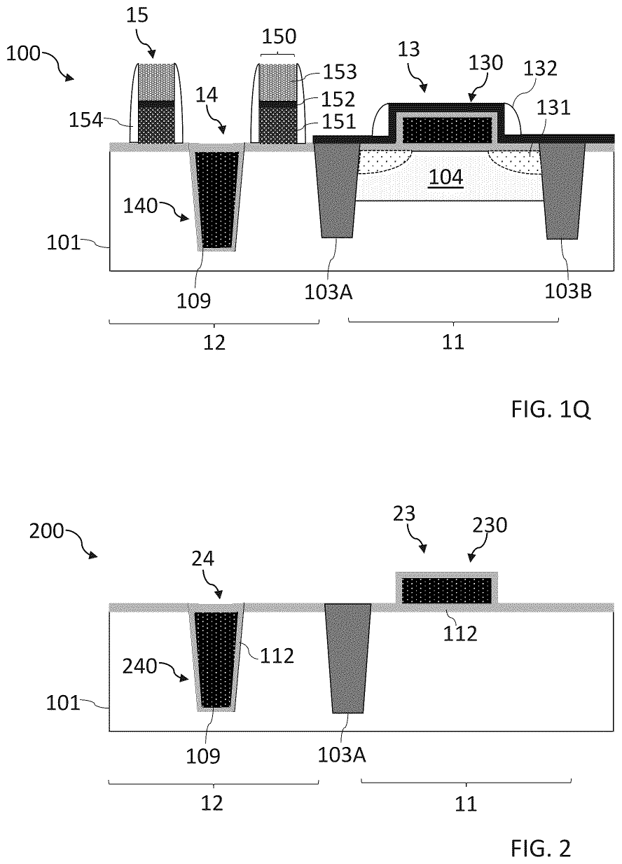

FIGS. 1A to 1Q are cross-section views showing a method of manufacturing an electronic device.

FIG. 1A shows an initial structure comprising a semiconductor substrate 101 covered with a layer 102 made of a dielectric material, or dielectric layer.

Semiconductor substrate 101 may be a solid-state semiconductor substrate, for example made of silicon, without this example being considered limiting. Semiconductor substrate 101 may be a semiconductor layer, for example a silicon layer, on a buried insulating layer of a Silicon On Insulator (SOI) structure. More generally, semiconductor substrate 101 may be any semiconductor substrate in which a trench may be formed.

Dielectric layer 102 is preferably an oxide layer, for example made of a silicon oxide, for example of silicon dioxide (SiO₂). According to variants, dielectric layer 102 may be made of other insulating materials, such as in particular SiON, HfSiON, ZrO₂, TiO₂, TaO₂ (non-limiting list).

Advantageously, the material of dielectric layer 102 may be selected to be less rapidly etchable, or even non-etchable, than silicon nitride (SiN). For example, the material of dielectric layer 102 may be selected to form an etch stop layer when the silicon nitride is etched. Dielectric layer 102 may form an interface layer between semiconductor layer 101, for example made of silicon, and a silicon nitride layer 105 described later on.

For example, dielectric layer 102 has a thickness in the range from 1 to 50 nm.

A first semiconductor region 11 is defined in semiconductor substrate 101 by first and second insulating trenches 103A, 103B. A second semiconductor region 12 is defined in semiconductor substrate 101, insulated from first semiconductor region 11 by the first insulating trench 103A. Although this is not shown, other semiconductor regions may be defined in semiconductor substrate 101.

A doping by ion implantation, schematized by the six vertical arrows, is carried out in first semiconductor region 11, from the upper surface of semiconductor substrate 101 covered by dielectric layer 102, in such a way as to form a doped well 104. For example, if first semiconductor region 11 is intended to form the drain, source, and channel regions of an NMOS transistor, the well is P doped. As a variant, if first semiconductor region 11 is intended to form the drain, source, and channel regions of a PMOS transistor, the well is N doped.

Although this is not shown, in order to clearly define the ion implantation area for forming doped well 104, a mask comprising, in particular, an opening located above first semiconductor region 11, for example between insulating trenches 103A, 103B, but covering other semiconductor regions, and in particular second semiconductor region 12, may be used. This mask may be a mask already used to implant other semiconductor regions (not shown), that is, open on these other semiconductor regions, and it may be provided to form in this existing mask this opening located above the first semiconductor region to implant this first semiconductor region.

FIG. 1B shows a structure obtained at the end of the deposition of a layer of silicon nitride 105 on dielectric layer 102.

The thickness e1 (first thickness) of silicon nitride layer 105 may be, for example, in the range from 50 to 200 nm, for example equal to approximately 80 nm. These values of thickness e1 are non-limiting, and thickness e1 may, for example, depend on the destructuring effect of silicon nitride desired in the step described hereafter.

FIG. 1C shows a structure obtained at the end of the forming of a first mask 106 on the upper surface of silicon nitride layer 105, then of the doping by ion implantation, schematized by the two vertical arrows, of silicon nitride layer 105 through the first mask 106.

The first mask 106 comprises a first opening 106A exposing a first portion 105A of silicon nitride layer 105 positioned above first semiconductor region 11, so that only first portion 105A is doped by ion implantation.

Other portions 105B, 105C of silicon nitride layer 105 are covered by this first mask 106. These other portions comprise, in particular, a second portion 105B located above second semiconductor region 12, and third portions 105C located on either side of first portion 105A above first semiconductor region 11.

The first mask 106 may be formed by deposition of a resist which is removed opposite the first portion 105A of silicon nitride layer 105.

Other portions of the silicon nitride layer above other semiconductor regions defined in the semiconductor substrate may be covered with the first mask. Further, the first mask may comprise a plurality of first openings exposing a plurality of first portions of the silicon nitride layer, so that the silicon nitride layer may comprise a plurality of first doped portions, for example above other semiconductor regions defined in the semiconductor substrate.

The ion implantation parameters are preferably determined so that the rate of etching of the first doped portion 105A is greater than the rate of etching of the undoped portions 105B, 105C of silicon nitride layer 105. The first portion 105A of silicon nitride layer 105 can be said to be “destructured” as a result of the ion implantation.

For example, the rate of etching of the doped silicon nitride may be up to 4 times, or 5 times, or even up to 10 times, higher than the rate of etching of the undoped silicon nitride.

The rate of etching of the doped silicon nitride may vary according to the type and/or to the number of implanted atoms. Those skilled in the art will know how to act on the type and/or the number of implanted atoms to increase the rate of etching of the doped silicon nitride. The rate of etching of the doped silicon nitride may be a function of the modification of the silicon nitride crystal lattice induced by the ion implantation.

The implantation energy may be selected to be able to reach the entire thickness of nitride layer 105 in the first portion 105A, but this is not limiting and it may not reach the entire thickness of nitride layer 105.

As an example, for a thickness e1 of silicon nitride layer 105 in the range from 60 to 200 nm, the implantation energy is in the range from 10 to 150 keV.

The implanted atoms may be selected from among argon, nitrogen, and phosphorus, but other atoms may be used. Those skilled in the art will be capable of selecting the right atoms according to the implemented manufacturing process.

FIG. 1D shows a structure obtained at the end of the removal of the first mask 106, and of the forming of a second mask 107 on the upper surface of silicon nitride layer 105, and then of the etching of a trench 109 through silicon nitride layer 105 and dielectric layer 102 and into the semiconductor substrate 101 across all or part of its thickness.

The second mask 107 comprises a second opening 107A exposing a fourth portion 105D of silicon nitride layer 105 positioned above second semiconductor region 12, the second mask covering the rest of the silicon nitride layer, so that the etching is localized inside of and under this fourth portion, and in second semiconductor region 12.

The second mask 107 may be formed by deposition of a resist which is removed opposite the fourth portion 105D of silicon nitride layer 105.

The second mask 107 may comprise a plurality of second openings exposing a plurality of fourth portions of the silicon nitride layer, so that a plurality of trenches may be formed, for example in other semiconductor regions defined in the semiconductor substrate.

The etching of trench 109 is preferably a dry etching, of plasma etching type.

In the shown example, trench 109 does not run through semiconductor substrate 101 across its entire thickness.

FIG. 1E shows a structure obtained at the end of the removal of second mask 107, and of the etching of silicon nitride layer 105. This etching is a partial etching since the silicon nitride layer is not entirely removed. This etching can be designated as a Nitride Pull Back (NPB) process.

During the NPB, the first doped portion 105A of silicon nitride layer 105 is etched faster than the undoped portions 105B, 105C of silicon nitride layer 105, typically at least 4 times or 5 times faster, and up to 10 times. It can be spoken of an over-etch factor. Thus, the etched silicon nitride layer 105′ has a cavity 111 located on the first etched portion 105A, without it being necessary to provide a specific mask to form this cavity, and with no dry etching which might generate parasitic charges and/or defectivity problems.

Thus, the first doped portion 105A is etched down to a first depth p1 equal to the first thickness e1, and the undoped portions 105B, 105C are etched down to a second depth p2 smaller than the first depth p1, for example much smaller than the first depth p1. The first depth p1 being equal to the first thickness e1, the first portion 105A is etched across its entire thickness e1, down to dielectric layer 102.

The etching of the silicon nitride is preferably a wet etching, based on a solution. The solution is, for example, a solution comprising phosphoric acid (H₃PO₄), or a solution based on diluted hydrofluoric acid (HF). Such a solution has an advantage of making the etching of silicon nitride highly selective over the silicon oxide that may form dielectric layer 102. Thus, the silicon nitride can be etched while keeping dielectric layer 102 virtually intact. The solution may advantageously be hot, for example at a temperature higher than or equal to 160° C.

The parameters of the etching of the silicon nitride, in particular the composition and the concentration of the solution, the duration and the temperature of the etching, may be selected so that the first depth p1 is equal to the first thickness e1. The second thickness p2 may, in particular, depend on the overetching factor and on the first thickness e1 to be etched in first portion 105A. As an example, the second depth p2 may be in the range from 10 to 50% of the first thickness e1.

The second depth p2 is, for example, equal to from approximately 10 to 20 nm for a thickness e1 in the range from 60 to 200 nm.

During this etch step, semiconductor substrate 101 is not etched. Dielectric layer 102 is also preferably not etched, and may form an etch stop layer.

In the shown example, it can be observed that this etching etches the silicon nitride more than the material, for example, the SiO₂, of dielectric layer 102, so as to form a lateral recess R of the silicon nitride above and on either side of trench 109. This lateral recess technique can also be designated by the term “Nitride Pull Back” (NPB), and enables to create a flared opening that may facilitate the subsequent filling of this trench. This lateral recess R may be in the range from 4 to 40 nm, for example from 10 to 20 nm.

FIG. 1F shows a structure obtained at the end of the deposition of a first layer of oxide 112, for example of silicon oxide, on the structure of FIG. 1E. The first oxide layer 112 comes on the bottom and on the sides of trench 109, on the bottom and on the sides of cavity 111, and on the etched silicon nitride layer 105′.

This step of deposition of first oxide layer 112 may be preceded by a step of removal of the exposed portions of dielectric layer 102, for example at least the portion 102A of the dielectric layer located at the bottom of cavity 111. This removal may be carried out by implementing a wet etching, for example with a solution of hydrofluoric acid (HF).

This first oxide layer 112 may form a gate insulator layer for future gate regions, for example to form future transistors in trench 109 and/or in cavity 111. This oxide may be deposited or formed by growth, for example of SiO₂ or SiON type, with a thickness of, for example, from 2 to 25 nm.

FIG. 1G shows a structure obtained at the end of the deposition of a first polysilicon layer 113 (filling layer) on first oxide layer 112. The first polysilicon layer 113 fills at least trench 109 and cavity 111, and may comprise a portion which extends above first oxide layer 112.

FIG. 1H shows a structure obtained at the end of the planarization of first polysilicon layer 113, to remove the portion which extends above first oxide layer 112, so that the polysilicon is flush with the upper surface of the etched silicon nitride layer 105′. This planarization is, for example, achieved by chemical mechanical polishing (CMP). During this polishing, exposed portions of first oxide layer 112 may also be removed, as shown.

There are thus formed a first polysilicon region 114 on first oxide layer 112 in cavity 111 above the first semiconductor region 11 of semiconductor substrate 101, and a second polysilicon region 115 on first oxide layer 112 in trench 109 in the second semiconductor region 12 of semiconductor substrate 101.

The first polysilicon region 114 may form a first gate region 130 in cavity 111, for example the gate region of a first transistor (first electronic component), for example a MOS transistor 13, as described hereafter in relation with FIG. 1Q. The thickness of the first polysilicon region 114, and thus of the first gate region 130, may be substantially equal to, or greater than or equal to, the depth p1 of the cavity, that is, the thickness e1 of silicon nitride layer 105. The thickness of the first polysilicon region 114 may be greater than 50 nm, or even greater than 100 nm, for example in the range from 50 to 200 nm.

The second polysilicon region 115 may form a second gate region 140 in trench 109, for example the gate region of a second transistor in a trench (second electronic component), for example a selection transistor 14, as described hereafter in relation with FIG. 1Q.

More generally, the embodiments enable to form a first polysilicon region on an oxide layer on a first semiconductor region of a semiconductor substrate, and a second polysilicon region on an oxide layer in a trench in a second semiconductor region of the same semiconductor substrate.

The following description shows that, according to the embodiment, a method of manufacturing a transistor in a trench in a semiconductor substrate can be carried out with no impact on the manufacturing of a planar transistor on the semiconductor substrate, and conversely. For example, the transistor in a trench and the planar transistor can be manufactured at the same time. The following description also shows that, after the forming of the cavity in the silicon nitride layer and the filling with polysilicon of this cavity, common manufacturing steps, for example, according to a same manufacturing process, can be implemented to form both types of transistors, and this, without having to multiply the number of masks. Further, the fact of doping a portion of the silicon nitride layer to then etch the silicon nitride selectively in this doped portion enables to avoid carrying out a dry etching, other than the dry etching for forming the trench. This thus enables to form a polysilicon region with no other dry etching (since a dry etching may have too strong an impact on nearby electronic components).

The following steps of the manufacturing method are specific to the forming of a transistor in a trench in the semiconductor substrate, such as a memory cell selection transistor, next to a MOS transistor on the semiconductor substrate. The manufacturing method may be adapted by those skilled in the art to manufacture other electronic components, including at least one electronic component in a trench in the semiconductor substrate and another electronic component on the semiconductor substrate.

FIG. 1I shows a structure obtained after an optional step of removal by etching of a thickness of polysilicon in trench 109, that is, the removal of a thickness e2 (second thickness) of polysilicon in the second polysilicon region 115, from the upper surface (first surface) of the etched silicon nitride layer 105′. As a non-limiting example, the removal may be performed so that the upper surface of the second etched polysilicon region 115′ arrives below the level of dielectric layer 102. This etching of the polysilicon is, for example, a dry etching. During this removal by etching of the polysilicon, first polysilicon region 114 is preferably protected by a mask 116, which is then removed from silicon nitride layer 105′. The portions 105C (third portions) of silicon nitride located above first semiconductor region 11 may also be protected by mask 116.

FIG. 1J shows a structure obtained at the end of the removal of the etched silicon nitride layer 105′. The removal of the silicon nitride may be performed by wet etching by means of a solution of phosphoric acid (H₃PO₄).

FIG. 1K shows a structure obtained at the end of the deposition of a second oxide layer 117 on the structure of FIG. 1J.

This step of deposition of second oxide layer 117 may be preceded by a step of removal of the exposed portions of dielectric layer 102. This removal may be performed by implementing a wet etching, for example with a solution of hydrofluoric acid (HF).

At the end of this step, there has been formed all or part of a planar gate with the first polysilicon region 114 above semiconductor substrate 101 co-integrated next to a vertical gate with the second polysilicon region 115 in trench 109. Starting from this structure, different electronic components may be formed, including at least one planar electronic component and one electronic component in a trench. FIGS. 1L to 1Q described hereafter show an example of electronic components that can be manufactured, that is, an example of co-integration, starting from the structure of FIG. 1J. This example comprises forming gate stacks on either side of the vertical gate to form memory cells, and a MOS transistor from the planar gate. This is a non-limiting example, and other examples of co-integration of a planar electronic component with a vertical, or trenched, electronic component may be envisaged by those skilled in the art.

FIG. 1L shows a structure obtained at the end of the deposition of a second layer of polysilicon 118 on the structure of FIG. 1K.

FIG. 1M shows a structure obtained at the end of the removal of a portion 118A of the second polysilicon layer 118 located above the first semiconductor region 11, for example by dry etching. Thus, the second polysilicon layer 118 is located above the second semiconductor region 12.

FIG. 1N shows a structure obtained at the end of the deposition of an oxide-nitride-oxide (ONO) layer 119 on the structure of FIG. 1M, and then of a third polysilicon layer 120 on ONO layer 119.

FIG. 1O shows a structure obtained at the end of the removal of a portion 120A of the third polysilicon layer 120 located above the first semiconductor region 11, for example by dry etching. Thus, the third polysilicon layer 120 is located above the second semiconductor region 12.

ONO layer 119 may be kept on the second oxide layer 117. The first polysilicon region 114 thus covered with the second oxide layer 117 and ONO layer 119 may form a first gate region 130 above the first semiconductor region 11.

FIG. 1P shows a structure obtained at the end of the forming of lightly-doped drain (LDD) regions 131 in the first semiconductor region 11 and of insulating spacers 132 on the sides of the first gate region 130. The drain and source regions may then be formed in the first semiconductor region 11, with a channel-forming region between these drain and source regions. Contact regions, for example via silicided regions, may be formed on the drain, source, and gate regions.

A MOS transistor 13 (first electronic component) is thus obtained.

FIG. 1Q shows a structure obtained at the end of the etching of the second polysilicon layer 118, of ONO layer 119, and of the third polysilicon layer 120 above the second semiconductor region 12, so as to form state transistors 15 of memory cells separated by a selection transistor 14 (second electronic component) having its gate region 140 in trench 109.

Each state transistor 15 comprises a gate region 150 comprising, for example, a floating gate 151 formed by a portion of the second polysilicon layer 118 topped with a control gate 153 formed by a portion of the third polysilicon layer 120, the control gate being insulated from the floating gate by a portion 152 of ONO layer 119. The gate region 150 of each state transistor 15 may be insulated by insulating spacers 154.

The electronic device 100 shown in FIG. 1Q thus comprises a MOS transistor 13 having its gate region 130 on semiconductor substrate 101 (on the first semiconductor region 11) next to state transistors 15 of memory cells separated by a selection transistor 14 having its gate region 140 in trench 109 in semiconductor substrate 101 (in the second semiconductor region 12). As previously indicated, this is a non-limiting example of co-integration of a planar electronic component with a vertical electronic component, but other examples of co-integration may be envisaged by those skilled in the art. In particular, starting from a technology for manufacturing an electronic component in a trench, the embodiments enable to form at least one planar electronic component.

FIG. 2 is a cross-section view showing an electronic device according to an embodiment. FIG. 2 more generally illustrates an electronic device 200 that can be obtained by a manufacturing method according to an embodiment.

Electronic device 200 comprises: a first electronic component 23 comprising a first gate region 230 on a first semiconductor region 11 of a semiconductor substrate 101; and a second electronic component 24 comprising a second gate region 240 in a trench 109 in a second semiconductor region 12 of the semiconductor substrate.

A gate insulator layer 112 is preferably comprised between the first gate region 230 and semiconductor substrate 101, and between the second gate region 240 and semiconductor substrate 101.

The first and second electronic components may be separated by a first insulating trench 103A.

For example, the thickness of the first gate region 230 is greater than 50 nm, or even greater than or equal to 100 nm, for example in the range from 50 to 200 nm.

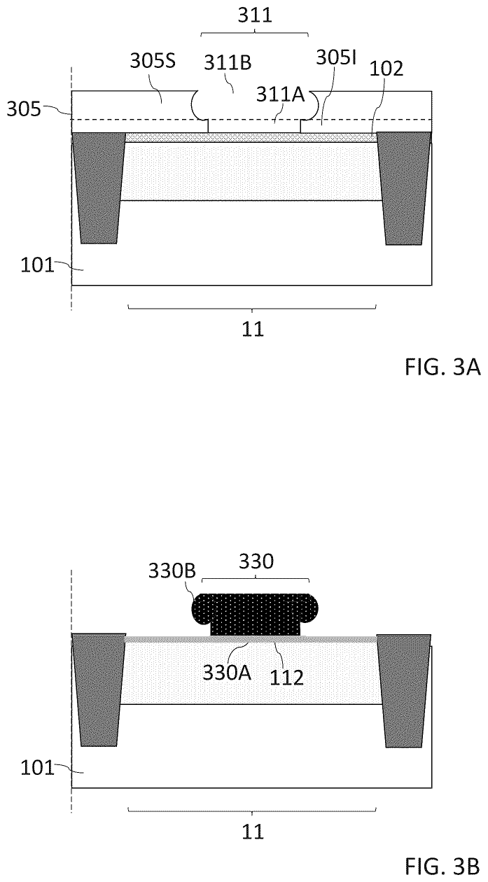

FIG. 3A and FIG. 3B are cross-section views showing a variant of the manufacturing method of FIGS. 1A to 1Q, in particular of the steps shown in FIGS. 1C to 1H. In FIGS. 3A and 3B, only the first semiconductor region 11 has been shown so as not to overload the drawing, but the second semiconductor region 12 may be present, as well as other semiconductor regions in the same semiconductor substrate 101.

According to this variant, as shown in FIG. 3A, the doping by ion implantation of silicon nitride layer 305 is carried out in such a way as to dope an upper portion 305S (second sub-layer) of the silicon nitride layer more than a lower portion 3051 (first sub-layer) of this silicon nitride layer in contact with dielectric layer 102. Thus, during the partial etching of silicon nitride layer 305, the cavity 311 formed in the silicon nitride may take a specific shape. In the shown example, cavity 311 comprises a lower portion 311A on dielectric layer 102, the lower portion being substantially cylindrical, and an upper portion 311B on the lower portion 311A, the upper portion 311B having a domed shape wider than the lower portion.

As shown in FIG. 3B, when cavity 311 is filled with the first polysilicon layer, such as the first polysilicon layer 113 of FIG. 1G, a first polysilicon gate region 330 may be obtained, which comprises a first portion 330A in contact with gate insulator layer 112 and a second portion 330B on the first portion 330A, the second portion 330B being wider than the first portion 330A, for example the first portion having a cylindrical shape and the second portion having a domed shape wider than the first portion. Other shapes of the first gate region are also possible.

This for example enables to decrease parasitic overlap capacitances between the gate region 330 formed in cavity 311, the gate insulator 112 under gate region 330, and the semiconductor substrate 101 under gate insulator 112.

More generally, the doping by ion implantation of the silicon nitride layer may be adapted to obtaining specific cavity shapes during the partial etching of the silicon nitride layer, so as to obtain a polysilicon region having a specific shape.

The electronic devices obtained by the described manufacturing methods, more generally by a manufacturing method according to an embodiment, may find applications in the fields of microcontrollers, of the Internet of Things (IoT), of analog circuits, of memories, for example non-volatile memories (NVM) or memories of Electrically Programmable Read-Only Memory (EEPROM) type.

Those skilled in the art will understand that certain features of these various embodiments and variants may be combined, and other variants will occur to those skilled in the art. In particular, a first planar electronic component adjacent to a second electronic component in a trench has been shown, but other configurations are possible. For example, one or a plurality of other electronic components may be provided between the electronic component in a trench and the planar electronic component. The first planar electronic component may be an electronic component different from a MOS transistor, for example, a capacitor, a resistor, etc. The second planar electronic component may be an electronic component different from a selection transistor, for example another transistor, a capacitor, etc. Further, a polysilicon layer for filling the trench and cavity has been described, but other conductive or semiconductor materials can be envisaged by those skilled in the art, for example materials for forming a High-K metal gate, or HKMG.

Finally, the practical implementation of the described embodiments and variants is within the abilities of those skilled in the art based on the functional indications given hereabove.

1. A method of manufacturing an electronic device, comprising:
providing a semiconductor substrate covered with a dielectric layer;
forming a silicon nitride layer having a first thickness on the dielectric layer;
doping by ion implantation a first portion of the silicon nitride layer located above a first semiconductor region of the semiconductor substrate, wherein a second portion of said silicon nitride layer located above a second semiconductor region of the semiconductor substrate is protected from said ion implantation; and
partially etching the silicon nitride layer, wherein a rate of etching of the first portion is greater than a rate of etching of the second portion so that the first portion is etched down by a first depth smaller than or equal to the first thickness and the second portion is etched down by a second depth smaller than the first depth, said partial etching forming an etched silicon nitride layer comprising a cavity in all or part of the first portion.

2. The method according to claim 1, wherein the rate of etching of the first portion is greater than four times the rate of etching of the second portion.

3. The method according to claim 1, wherein etching the first portion stops before, or at, the dielectric layer, the dielectric layer forming an etch stop layer for the silicon nitride, the dielectric layer being made of silicon oxide.

4. The method according to claim 1, comprising forming an insulating trench in the semiconductor substrate between the first semiconductor region and the second semiconductor region, wherein forming said insulating trench is performed prior to forming the silicon nitride layer.

5. The method according to claim 1, comprising forming a trench in the second semiconductor region through the silicon nitride layer and the dielectric layer, wherein forming the trench is performed prior to partially etching the silicon nitride layer.

6. The method according to claim 5, wherein forming the trench comprises performing a dry etching.

7. The method according to claim 5, comprising forming a polysilicon filling layer which fills the cavity and the trench, said polysilicon filling layer forming a first polysilicon region in said cavity and a second polysilicon region in said trench.

8. The method according to claim 7, comprising forming, prior to forming the filling layer, a first layer of oxide on sides and bottoms of the cavity and the trench.

9. The method according to claim 7, comprising removing the etched silicon nitride layer, after the forming the filling layer, wherein removing comprises performing a wet etching with a solution comprising phosphoric acid.

10. The method according to claim 9, comprising forming a second oxide layer on the first and second polysilicon regions, wherein forming the second oxide layer is carried out after removing the etched silicon nitride layer.

11. The method according to claim 10, wherein the second oxide layer is further formed on portions of the semiconductor substrate from which the dielectric layer has been removed.

12. The method according to claim 7, wherein the first polysilicon region forms all or part of a first gate region of a first electronic component, said first gate region being on the first semiconductor region, and the second polysilicon region forms all or part of a second gate region of a second electronic component, said second gate region being in a trench in the second semiconductor region.

13. The method according to claim 12, wherein the first component is a MOS transistor, and wherein the second component is a transistor in a trench.

14. The method according to claim 7, comprising removing a second thickness of polysilicon in the second polysilicon region from a first surface of the etched silicon nitride layer, wherein the first polysilicon region is protected by a mask during removal of the second thickness.

15. The method according to claim 1, wherein partially etching the silicon nitride layer comprises performing a wet etching using one of: a solution comprising phosphoric acid, or a solution based on hydrofluoric acid.

16. The method according to claim 1, wherein the first depth is greater than or equal to 80% of the first thickness.

17. The method according to claim 1, wherein the first depth is substantially equal to the first thickness.

18. The method according to claim 1, wherein the second depth is smaller than or equal to 50% of the first thickness.

19. The method according to claim 1, wherein doping the first portion of the silicon nitride layer is configured to less heavily dope a first sublayer in contact with the dielectric layer than a second sublayer above the first sublayer, and wherein partially etching the silicon nitride layer forms the cavity in the silicon nitride layer which comprises a first portion corresponding to the less heavily doped first sublayer and a second portion corresponding to the more heavily doped second sublayer, the second portion being wider than the first portion.

20. The method according to claim 19, wherein the first portion has a cylindrical shape and the second portion has a domed shape wider than the first portion.

21. An electronic device, comprising:
a first electronic component comprising a first gate region on a first semiconductor region of a semiconductor substrate; and
a second electronic component comprising a second gate region in a trench in a second semiconductor region of the semiconductor substrate,
wherein the first gate region has a thickness greater than 50 nm.

22. The electronic device according to claim 21, where the thickness of the first gate region is greater than or equal to 100 nm.

23. The electronic device according to claim 21, wherein the first gate region comprises a first portion on the semiconductor substrate and a second portion on the first portion, the second portion being wider than the first portion.

24. The electronic device according to claim 23, wherein the first portion has a cylindrical shape and the second portion has a domed shape wider than the first portion.
